(19) United States
(12) Patent Application Publication
(10) Pub. No.: US 2016/0255723 A1
(43) Pub. Date: Sep. 1, 2016

(54) CONDUCTOR FUSE

(71) Applicant: TRIDONIC GMBH & CO KG, Dornbirn (AT)

(72) Inventor: Sascha STEINER, Dornbirn (AT)

(73) Assignee: TRIDONIC GMBH & CO KG, Dornbirn (AT)

(21) Appl. No.: 15/150,181

(22) Filed: May 9, 2016

Related U.S. Application Data
(63) Continuation of application No. 13/995,822, filed on Jul. 25, 2013.

(30) Foreign Application Priority Data
Dec. 22, 2010 (DE) 10 2010 063 832.3

(51) Int. Cl. H05K 1/16; H01H 85/38; H01H 85/046

(52) U.S. Cl. CPC H05K 1/16; H01H 85/046; H01H 85/38; H01H 2085/388

(57) ABSTRACT

Conductor fuse (1), for an electrical or electronic device, has a first and a second connecting region (2a, 2b), a planar linearly extending burn-through region (3) arranged between the first and the second connecting region, and a contiguous covering region (4) which is arranged at least partially over the first and the second connecting region (2a, 2b) and the burn-through region (3). The burn-through region (3) and the covering region (4) are arranged on a circuit board (20) mutually to each other in such a way that at least one trigger region (3a) of the burn-through region (3) is not covered by the covering region (4), but is instead limited by the covering region.

### INCORPORATION BY REFERENCE

This application is a continuation of U.S. patent application Ser. No. 13/995,822, filed Jul. 25, 2013, which is a National Stage entry of PCT/EP2011/072155 filed Dec. 8, 2011, which claims the benefit of German Application Serial No. 10 2010 063 832.3 filed Dec. 22, 2010, which are incorporated by reference as if fully set forth.

### FIELD OF THE INVENTION

The invention relates to a conductor fuse for electrical protection of electronic devices.

### BACKGROUND

Conductor fuses are known from the prior art. They are installed on a circuit board and their purpose is to quickly and reliably break the electrical connection supplying power in case of an abnormal device status, such as for example short circuiting of electrical components of the circuit board. This makes it possible to avoid further damage to the circuit board or to the electrical components located on it. In addition, it is also possible to prevent triggering off a power circuit breaker with an early activation of the conductor fuse.

By providing a conductor fuse on a circuit board, it is additionally also possible to replace a precision fuse which is otherwise customarily used for protection of electrical or electronic devices.

The conductor fuse is generally equipped with at least one conductor path section which is designed as a fusible safety fuse or a fusible conductor. This conductor path section has a narrower cross-section in comparison with other conductor paths on the circuit board. The fuse element is heated by the current flowing through the element and it is melted or vaporized when the rated current of the fuse element has been significantly exceeded, which results in circuit interruption.

It is important in this case to ensure that the arc, which can be potentially generated, will be extinguished in a controlled manner and in particular that no other conductor lines can be reached. It is in particular important to prevent the possibility that plasma generated by the melting or vaporization of the fuse element finds a pair of contacts under voltage and thus causes uncontrolled further burning and further damage to the circuit board.

DE 100 05 836 B4 describes a circuit board for an electrical or electronic device provided with a circuit board fuse, wherein the circuit board carries a conductor line to be protected, and wherein the conductor line is provided with a non-conductive coating which has a reduced cross-section compared to the burn-through area. In addition, the conductor line is provided in addition to the coating with at least two accumulations of non-conductive material which are arranged at a distance from each other in the direction of the conductor line.

### SUMMARY

Based on this existing technology, the object of the invention is to provide a conductor fuse, which can be produced inexpensively for a conductor board or circuit board, and which in the event of a fault enables safe and secure switching off of the power supply and thus improves operational safety.

This object is achieved according to the invention with the characteristics of the independent claims. Particularly advantageous embodiments of the invention are described in the dependent claims.

In a first aspect, the present invention relates to a conductor fuse for an electrical or electronic device, provided with a first and a second connecting region, a burn-through region, which is arranged between the first and the second connecting region, without being linearly extended, and a contiguous covering region, which is arranged at least partially over the first and the second connecting region and the burn-through region, wherein the burn-through region and the covering region are arranged relative to each other in such a way that at least one trigger region of the burn-through region is not covered by the covering region, but is instead limited on both sides by the covering region.

The present invention makes it possible to manufacture in a simple manner and at the same time very efficiently a conductor fuse, which makes it possible to increase the operational safety of an electric or electronic device.

In a preferred embodiment of the invention, the burn-through region is provided, in top plan view, with a course which is at least partially curved or partially zigzag-shaped. This curved or zigzag-shaped pathway of the burn-through region is thus preferably extended along a main extension direction of the burn-through region. This main extension direction of the burn-through region corresponds preferably to a direct connection of the first and second connecting region of the conductor path view in top plan view. The curved or zigzag-shaped pathway of the burn-through region is preferably extended to both sides of the main extension direction of the burn-through region to the same extent.

In another preferred embodiment, the curved or zigzag-shaped pathway can be shaped distinctly in such a way that this course of the burn-through zone is further extended to one side of the main direction of the burn-through zone, rather than to one of the opposite side of the main direction.

In addition, the burn-through zone can also be provided with a different, non-linear course.

The associated covering region of the conductor fuse is preferably arranged parallel to the main direction of the burn-through zone. The covering region is in this case preferably arranged linearly between the first and the second connecting region.

It is therefore possible to arrange the covering region directly between the first and the second connecting region on the circuit board. The first and the second connecting regions are thus preferably covered at least partially by the covering region. A simplified attachment of the covering region is therefore achieved in this manner.

In a preferred embodiment, the covering region is formed homogeneously. In particular, the covering region is preferably provided with a constant thickness. In addition, the covering region is manufactured from a continuous, homogeneous material. The covering region is preferably a bar or a strip made from a non-conductive material, for example from an SMD adhesive or a solder resist.

The covering region is preferably provided with a constant width when viewed from above.

The covering region is preferably a film made of non-conductive material. The covering region can be applied onto the circuit board with a template and subsequently with optional squeegeeing.

It is therefore possible to apply the covering region in one procedural step over the burn-through region of the conductor fuse, without requiring further processing steps. The time required for the manufacturing as well as the manufacturing costs can thus be reduced. At the same time, a reliable protection of the circuit board is ensured by means of the conductor fuse according to the invention.

The burn-through region of the conductor fuse is preferably a copper conductor, which is not plated with tin and which is provided with a reduced cross-section relative to the first and second connecting region. However, the burn-through region can be also formed from another material such as for example fine silver. The cross-section of the burn-through region is preferably between 0.05 to 1 mm.

The at least one trigger region of the burn-through region is arranged in top plan view laterally to the contiguous covering region. At least one trigger region is thus limited on both sides by the covering region. Accordingly, it is advantageous when at least one non-linear trigger region is arranged laterally to the covering region.

If the burn-through region is impacted by a current which clearly exceeds the rated current, vaporization or melting of the burn-through region will occur.

In this case, the amount of the material that can be vaporized with such triggering is kept to a minimum because only a small area of the burn-through region, namely the at least one trigger region, is not covered by the covering material. The remaining part of the burn-through region which is covered by the covering region is cooled during such a triggering event by the non-conductive material applied to it.

The conductor fuse is therefore provided in this manner with a defined trigger region, whereby the plasma generated during the vaporization of the burn-through region is kept to a minimum.

In a preferred embodiment, the surface ratio between the trigger region of the burn-through region to the covered part of the burn-through region is between ⅓ and 1/9.

The at least one trigger region may comprise insulation or an insulation layer. This is preferably applied in an additional layer on the at least one trigger region. The insulation can in this case cover the trigger region and/or at least partially the insulation layer. The insulation layer can be for example formed from epoxy resin, or can be a silicon compound.

In a second aspect, the present invention describes a circuit board comprising a conductor fuse which has the characteristics described above.

The present invention therefore makes it possible to increase the operational safety of the circuit board with a circuit board fuse which is easy to manufacture.

In another aspect, the present invention describes an operating circuit for a lighting means which is provided with a conductor fuse according to the invention.

### BRIEF DESCRIPTION OF THE DRAWINGS

Advantageous embodiments of the present invention which are described in the attached figures will be described in detail as follows.

FIG. 1 shows a schematic top plan view of the conductor fuse according to a first embodiment of this invention.

FIG. 2 shows a schematic top plan view of the conductor fuse according to a second embodiment of this invention.

FIG. 3 shows a schematic top plan view of the conductor fuse according to a third embodiment of this invention.

FIG. 4 shows a schematic top plan view of the conductor fuse according to FIGS. 1 through 3.

FIG. 5 shows a circuit board of an electrical or electronic device provided with a conductor fuse according to the invention.

### DETAILED DESCRIPTION OF THE EMBODIMENTS

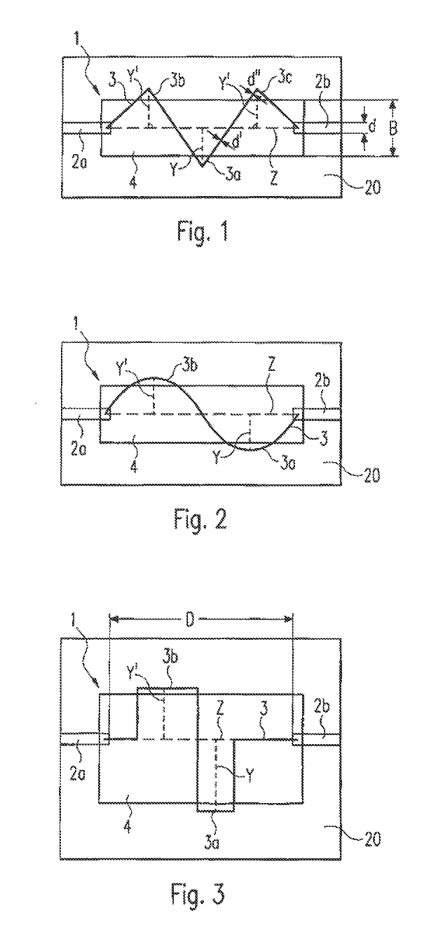

FIG. 1 shows a schematic top plan view of the conductor fuse 1 according to a first embodiment of the invention. The conductor fuse 1 is attached to a conductor plate or circuit board 20, and it is provided with a first and second connecting region 2a, 2b. The connecting regions 2a, 2b are arranged at a distance D (see FIG. 3), which is for example between 3 and 15 cm.

Between the first and second connecting region 2a, 2b is arranged a burn-through region 3 which is in electrical contact with these regions. The burn-through region is provided with a cross-section d′ which is reduced in comparison with the cross-section d of the first and of the second connecting region 2a, 2b. It is advantageous when the cross-section d′ of the burn-through region 3 is reduced also relative to the other conductor paths 5, 6 which are located on the circuit board 20 (see FIG. 5).

The cross-section d′ of the burn-through regions 3 is thus dimensioned in such a way that the burn-through region will become vaporized or melted when the rated current of the conductor fuse 1 is exceeded.

The burn-through region 3 is preferably arranged non-linearly between the first and the second connecting region 2a, 2b. In a preferred embodiment, the burn-through region 3 is provided with a zigzag-shaped pathway which is extended along a main extension direction Z.

The main extension direction Z in this case preferably corresponds to the direct or the shortest connection between the first and the second connecting region 2a, 2b.

The zigzag-shaped pathway of the burn-through region 3 is preferably extended by the same extent Y, Y′ to both sides of the main extension direction Z. However, it is also possible for the zigzag-shaped pathway to be extended with a different extent Y, Y′ from the main extension direction Z.

A covering region 4 is arranged over the first and the second direction 2a, 2b, as well as over the burn-through regions 3. This covering region covers in top plan view at least partially the first and the second connecting region 2a, 2b, and the burn-through region 3.

The covering region 4 is shown as being transparent in the FIGS. 1 through 3 in order to simplify the explanation. Accordingly, the conductor path of the burn-through region 3 located below it, as well as the first and the second connecting region 2a, 2b are fully visible.

The covering region 4 is preferably arranged with respect to the burn-through region 3 in such a way that at least one trigger region 3a of the burn-through region 3 is not covered by the covering region 4. Accordingly, the at least one trigger region 3a will thus be vaporized or melted as quickly as possible and in a controlled manner if the conductor fuse is impacted with a current which clearly exceeds the rated current, without causing at the same time spreading of the plasma generated in this manner to other conductive contacts or to contacts of the conductor fuse in which the current is flowing. This is prevented in particular through the covering region 4 which limits on both sides the at least one trigger region 3a of the conductor fuse.

Evaporation or melting of the remaining burn-through region 3, when plasma is created, is prevented by the covering region 4, which cools the conductor path 3 located below it.

The cross-section d″ of at least one trigger region 3a is preferably equal to the cross-section d′ of the burn-through region 3.

In an alternative embodiment, the at least one trigger region 3a is provided with a further reduced cross-section d″ opposite the cross-section d′ of the burn-through region 3.

In another preferred embodiment, the conductor fuse 1 is provided with several trigger regions 3a. Three trigger regions 3a, 3b, 3c are preferably provided, so that each of them is limited by the covering region 4 on both sides.

The covering region 4 is arranged linearly between the first and the second connecting region 2a, 2b and therefore it follows the main extension direction Z of the burn-through region 3 on the circuit board 20. The covering region 4 is thus provided with a constant width B. Width B is preferably smaller than the sum of the extension lengths Y and Y′ of the burn-through region 3, which are arranged at right angles to the main extension direction Z.

The covering region 4 is further preferably arranged in the central region with respect to the main extension direction Z on the circuit plate 20.

FIGS. 2 and 3 show a schematic top plan view of the conductor fuse according to a second and third embodiment. These embodiments essentially correspond to the embodiment according to FIG. 1 where the same structural parts are labeled with the same reference symbols.

According to the embodiment shown in FIG. 2, the burn-through region 3 is provided with at least partially curved course. The at least one trigger region 3a is here again limited by the covering region 4 on both sides.

Another preferred embodiment is shown in FIG. 3, wherein the burn-through region 3 is provided with a course which is at least partially angular or rectangular.

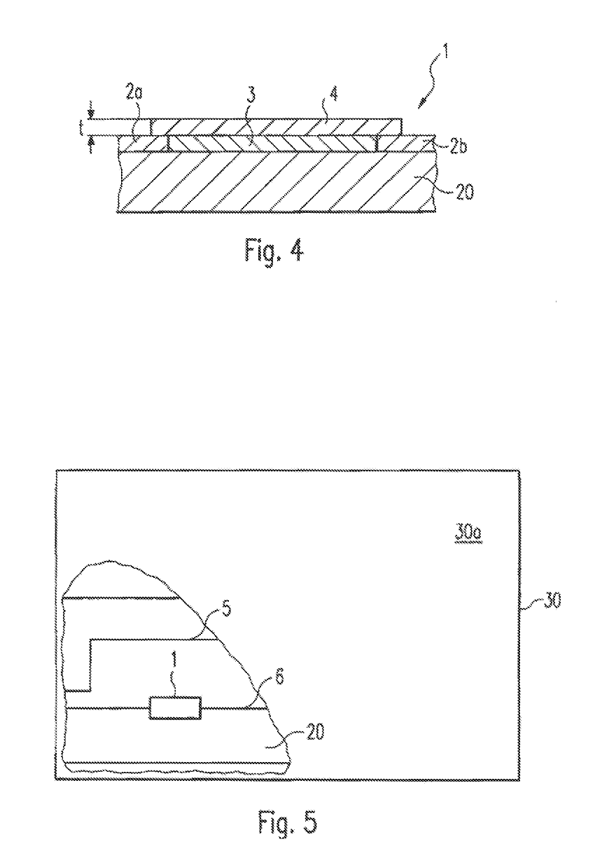

FIG. 4 shows a schematic lateral view of the conductor fuse according to the FIGS. 1 and 2. As illustrated in this figure, the first and second connecting regions 2a, 2b are mounted directly on the circuit board 20. Similarly, the burn-through region 3 is mounted directly on the circuit board 20 between the first and the second connecting region 2a, 2b.

The covering region 4 is attached in another layer at least over the entire length of the burn-through region 3. The covering region 4 is thus extended at least continuously along the entire main extension direction Z between the first and the second connecting region 2a, 2b.

The covering region 4 preferably has the same thickness t. This thickness is preferably from 0.3 to 2 mm.

The conductor fuse according to the invention can thus be manufactured in a simplified manner. Here, the connecting regions 2a, 2b, which are preferably electrically connected with other conductor paths of the circuit board 20, are mounted together with the conductor paths on the circuit board 20.

In the same procedural step or in a procedural step immediately following this step, the conductor path forming the burn-through region 3 can be applied between the first and the second connecting region 2a, 2b on the circuit board 20.

By the term “applying” the conductor path onto the conductor plate 20, an etching of the relevant conductor path in a thin copper layer which is located on the conductor plate should, in particular, be understood.

The covering region 4 can be attached in a subsequent procedural step over the burn-through region 3. The covering region 4 is thus preferably applied by means of a template. A uniform thickness of the covering region 4 can be achieved with squeegeeing in a step taking place at the same time.

The at least one trigger region 3a, 3b, 3c can optionally be coated with an additional layer consisting of an insulating material (not shown in the figure). This material can be attached before or after the application of the covering region 40 to the circuit board 20. The insulating material can thus be used as protection against corrosion, or as protection against accidental contact.

As shown in FIG. 4, the covering region 4 is stamped out like a film, which is preferably made from non-conductive materials, for example a solder resist or an SMD adhesive.

In addition, the covering region 4 and/or the optional insulation layer can also contain arc extinguishing substances.

When the covering region 4 is formed with an SMD adhesive, the application of the covering region 4 is preferably carried out in the same step in which the adhesive spots are to be applied to the circuit board 20 during the manufacturing of the circuit board.

The selective covering of the burn-through region 3 by means of the covering region 4 can thus be carried out in one step along with the application of the adhesive spots to the circuit board 20.

A simplified manufacturing process is therefore enabled for the manufacturing of the conductor plate 20.

FIG. 5 shows a ballast unit 30 for a lighting means, equipped with a circuit board 20 onto which is mounted the operating circuit of conductor paths 5, 6 forming the lighting means. The ballast device 30 is in this case provided with a conductor fuse 1 according to the invention.

The circuit board 20 is thus located in the inner part of a housing 30a of the unit 30. The conductor paths 5, 6 are in contact with an external power supply, not shown in the figure, supplying for example a 230V line.

The conductor path 6 is in electrical contact with a conductor fuse 1. An electrical fuse of the conductor path 6 is thus enabled for the electrical device 30. A short circuit occurring in the circuit or an abnormal operating status which leads to a current in the conductor paths 5, 6, which clearly exceeds the rated current of the conductor fuse 1, can thus be safely interrupted by the conductor fuse 1.

1. Conductor track fuse (1) for an electrical or electronic appliance, having a first and a second connection region (2a, 2b), a burn-out region (3) which is arranged between the first and the second connection region (2a, 2b) and does not extend in a linear manner, and a cohesive covering region (4) which is arranged at least in each case partially above the first and the second connection region (2a, 2b) and the burn-out region (3), wherein the burn-out region (3) and the covering region (4) are arranged in relation to one another in such a way that at least one trip region (3a) of the burn-out region (3) is not covered by the covering region (4) but is bounded on both sides by the covering region, wherein the cohesive covering region (4) is arranged parallel to a main direction (Z) of extent of the burn-out region (3), wherein the main direction (Z) of extent corresponds to a direct connection of the first and the second connection region (2a, 2b) in plan view; wherein the covering region (4) has a constant width (B) in plan view.

2. The conductor track fuse according to claim 1, wherein the burn-out region (3) has a zigzag profile in plan view.

3. The conductor track fuse according to claim 1, wherein the burn-out region (3) has an at least partially bent or angled profile in plan view.

4. The conductor track fuse according to claim 1, wherein the burn-out region (3) has a cross section (d′) which is reduced in comparison to the first and the second connection region (2a, 2b).

5. The conductor track fuse according to claim 1, wherein the covering region (4) is of homogeneous design and has a constant thickness (t).

6. The conductor track fuse according to claim 1, wherein the at least one trip region (3a) of the burn-out region (3) is arranged to the side of the continuous covering region (4) in plan view.

7. The conductor track fuse according to claim 1, wherein the at least one trip region (3a) has an insulation.

8. The conductor track fuse according to claim 1, wherein the burn-out region (3) is a bare copper conductor.

9. The conductor track fuse according to claim 1, wherein the covering region (4) is a bar or strip which is composed of non-conducting material, which is SMD adhesive or solder stop finish.

10. The conductor track fuse according to claim 1, wherein the covering region (4) can be applied with the aid of a stencil.

11. The conductor track fuse according to claim 1, wherein a profile of the burn-out region (3) extends further to one side of the main direction (Z) of extent than to an opposite side of the main direction (Z) of extent.

12. The conductor track fuse according to claim 1, wherein a ratio of the trip region (3a) of the burn-out region (3) to the covered region of the burn-out region (3) is between ⅓ and 1/9.

13. The conductor track fuse according to claim 4, wherein a cross section (d″) of the trip region (3a) of the burn-out region (3) is smaller than the cross section (d′) of the covered region of the burn-out region (3).

14. A printed circuit board having a conductor track fuse according to claim 1.

15. An operating circuit for lighting means having a conductor track fuse according to claim 1.
